(19) United States
(12) Patent Application Publication
(10) Pub. No.: US 2025/0261485 A1
(43) Pub. Date: Aug. 14, 2025

(54) LIGHT-EMITTING DIODE CHIP STRUCTURES WITH ELECTRODE EXTENSIONS AND VIAS

(71) Applicant: CreeLED, Inc., Durham, NC (US)

(72) Inventors: David Suich, Durham, NC (US); Michael Check, Holly Springs, NC (US); Joseph G. Sokol, Durham, NC (US); Natalia da Silva Moura, Durham, NC (US); Colin Blakely, Raleigh, NC (US)

(21) Appl. No.: 18/436,807

(22) Filed: Feb. 8, 2024

(51) Int. Cl. H01L 33/38; H01L 25/075; H01L 33/30; H01L 33/62

(52) U.S. Cl. CPC H10H 20/831; H01L 25/0753; H10H 20/824; H10H 20/857

(57) ABSTRACT

Solid-state lighting devices including light-emitting diode (LED) chips and more particularly LED chip structures with electrode extensions and vias are disclosed. Electrode extensions and vias are formed on opposing sides of an active LED structure as part of anode and cathode connections. Electrode extensions are formed with various shapes in positions relative to closest vias to promote improved recombination efficiency in active LED structures. Recombination efficiency is higher in regions between electrode extensions and closest vias where higher electrostatic field strength is exhibited. Layouts of vias relative to electrode extensions are disclosed with improved uniformity in spacings relative to areas of higher electrostatic field strength to increase emission efficiency of LED chips.

### FIELD OF THE DISCLOSURE

The present disclosure relates to solid-state lighting devices including light-emitting diode (LED) chips and more particularly to LED chip structures with electrode extensions and vias.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from gallium nitride, gallium phosphide, aluminum nitride, and/or gallium arsenide-based materials and/or from organic semiconductor materials, among others. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by how well current is able to spread within an LED. To increase current spreading for LEDs, and in particular for larger area LEDs, it has been found useful to add layers of high electrical conductivity over one or more epitaxial layers of an LED. Electrodes for the LEDs can have larger surface areas and may include various electrode extensions or fingers that are configured to route and distribute current across an LED.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diode (LED) chips and more particularly to LED chip structures with electrode extensions and vias. Electrode extensions and vias are formed on opposing sides of an active LED structure as part of anode and cathode connections. Electrode extensions are formed with various shapes in positions relative to closest vias to promote improved recombination efficiency in active LED structures. Recombination efficiency is higher in regions between electrode extensions and closest vias where higher electrostatic field strength is exhibited. Layouts of vias relative to electrode extensions are disclosed with improved uniformity in spacings relative to areas of higher electrostatic field strength to increase emission efficiency of LED chips.

In one aspect, an LED chip comprises: an active LED structure comprising a first layer of a first conductivity type, a second layer of a second conductivity type that is opposite the first conductivity type, and an active layer between the first layer and the second layer; an electrode extension on a first side of the active LED structure; and a plurality of vias on a second side of the active LED structure opposite the first side, the electrode extension curving on the first side of the active LED structure in positions that are laterally spaced from areas of the active LED structure that are vertically aligned with each via of the plurality of vias. In certain embodiments, the plurality of vias are arranged in a linear column along the second side of the active LED structure. In certain embodiments, the electrode extension forms a serpentine shape relative to the linear column. In certain embodiments, the electrode extension extends on portions of the active LED structure that are between areas of the active LED structure vertically aligned with adjacent pairs of vias of the linear column. In certain embodiments, the active LED structure comprises a group III-V material. In certain embodiments, the active LED structure comprises aluminum indium gallium phosphide (AlInGaP). In certain embodiments, the active LED structure is configured to provide a peak wavelength in a range from 600 nanometers (nm) to 700 nm. In certain embodiments, the active LED structure is configured to provide a peak wavelength in a range from 650 nm to 670 nm. In certain embodiments, the active LED structure is configured to provide a peak wavelength in a range from 610 nm to 630 nm. In certain embodiments, the electrode extension forms a spiral shape on the first side of the active LED structure. In certain embodiments: the electrode extension is one of a plurality of electrode extensions on the first side of the active LED structure; and each electrode extension of the plurality electrode extensions forms a concentric ring on the first side of the active LED structure. The LED chip may further comprise an additional electrode extension that electrically couples at least two concentric rings together.

In another aspect, an LED chip comprises: an active LED structure comprising a first layer of a first conductivity type, a second layer of a second conductivity type that is opposite the first conductivity type, and an active layer between the first layer and the second layer; a plurality of electrode extensions on a first side of the active LED structure, each electrode extension of the plurality of electrode extensions forming a serpentine shape along the first side of the active LED structure; and a plurality of vias arranged on a second side of the active LED structure opposite the first side. In certain embodiments: the plurality of vias is arranged in a plurality of linear columns along the second side of the active LED structure; and the serpentine shape of at least one electrode extension of the plurality of electrode extensions extends along portions of the active LED structure that are between areas of the active LED structure vertically aligned with adjacent pairs of vias of a linear column of the plurality of linear columns. In certain embodiments, the plurality of vias form at least one serpentine pattern on the second side of the active LED structure in a position that is laterally spaced from areas of the active LED structure vertically aligned with each electrode extension of the plurality of electrode extensions. In certain embodiments, the plurality of vias are positioned such that a distance between any point on an edge of at least one electrode extension of the plurality of electrode extensions to a closest via of the plurality of vias varies by no more than twenty five percent along the at least one electrode extension, the distance being measured from a first plane aligned with the edge of the at least one electrode extension to a second plane aligned with a closest edge of the closest via of the plurality of vias. In certain embodiments, the active LED structure is configured to provide a peak wavelength in a range from 600 nanometers (nm) to 700 nm.

In another aspect, an LED chip comprises: an active LED structure comprising a first layer of a first conductivity type, a second layer of a second conductivity type that is opposite the first conductivity type, and an active layer between the first layer and the second layer; an electrode extension on a first side of the active LED structure; and a plurality of vias on a second side of the active LED structure opposite the first side of the active LED structure, the plurality of vias positioned such that a distance between any point on an edge of the electrode extension to a closest via of the plurality of vias varies by no more than twenty five percent along the electrode extension, the distance being measured from a first plane aligned with the edge of the electrode extension to a second plane aligned with a closest edge of the closest via of the plurality of vias. In certain embodiments, the distance varies by no more than ten percent along the electrode extension. In certain embodiments, the distance varies by no more than five percent along the electrode extension. In certain embodiments, the active LED structure is configured to provide a peak wavelength in a range from 600 nanometers (nm) to 700 nm.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-section of a portion of a light-emitting diode (LED) chip illustrating an electrode extension and a via arranged on opposing sides of an active LED structure according to principles of the present disclosure.

FIG. 2A is a top view of an LED chip with an exemplary layout of electrode extensions and vias of FIG. 1.

FIG. 2B is a top view of a portion of the LED chip of FIG. 2A illustrating the variable distance between electrode extensions and the closest vias.

FIG. 2C is a top view of the portion of the LED chip of FIG. 2B illustrating variations in electrostatic field strength with distance between electrode extensions and vias.

FIG. 3A is a top view of an LED chip with an improved layout of electrode extensions and vias for enhanced emission efficiency.

FIG. 3B is a top view of a portion of the LED chip of FIG. 3A illustrating the more uniform distance between the electrode extensions and the closest vias.

FIG. 3C is a top view of the portion of the LED chip of FIG. 3B illustrating a more uniform electrostatic field strength between electrode extensions and vias.

FIG. 4A is a top view of an LED chip with another improved layout of electrode extensions and vias for enhanced emission efficiency.

FIG. 4B is a top view of a portion of the LED chip of FIG. 4A illustrating the more uniform distance between the electrode extensions and the closest vias.

FIG. 5 is a top view of an LED chip with another improved layout where the electrode extension has a spiral shape relative to the vias for enhanced emission efficiency.

FIG. 6 is a top view of an LED chip with another improved layout where the electrode extensions form concentric rings relative to the vias for enhanced emission efficiency.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diode (LED) chips and more particularly to LED chip structures with electrode extensions and vias. Electrode extensions and vias are formed on opposing sides of an active LED structure as part of anode and cathode connections. Electrode extensions are formed with various shapes in positions relative to closest vias to promote improved recombination efficiency in active LED structures. Recombination efficiency is higher in regions between electrode extensions and closest vias where higher electrostatic field strength is exhibited. Layouts of vias relative to electrode extensions are disclosed with improved uniformity in spacings relative to areas of higher electrostatic field strength to increase emission efficiency of LED chips.

An LED chip typically comprises an active LED structure or region that can have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group Ill nitride-based material systems. Group Ill nitrides refer to those semiconductor compounds formed between nitrogen (N) and the elements in Group III of the periodic table, usually aluminum (AI), gallium (Ga), and indium (In). Gallium nitride (GaN) is a common binary compound. Group Ill nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group Ill-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit generally red or yellow light with a peak wavelength range of 600 nm to 700 nm. Certain embodiments as disclosed herein may be well suited for various sub-ranges within 600 nm to 700 nm, such as a peak wavelength range from 650 nm to 670 nm and/or a peak wavelength range from 610 nm to 630 nm, depending on the application. In certain embodiments, aspects of the present disclosure are applicable to an active LED structure that emits light with a peak wavelength in any area of the visible spectrum, for example peak wavelengths primarily in a range from 400 nm to 700 nm.

In still further embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. In certain embodiments, a “light-transmissive” material may be configured to transmit at least 50% of emitted radiation of a desired wavelength.

The present disclosure can be useful for LED chips having a variety of geometries, including vertical geometries. A vertical geometry LED chip typically includes anode and cathode connections on opposing sides or faces of the LED chip. In certain embodiments, a vertical geometry LED chip may also include a growth substrate that is arranged between the anode and cathode connections. In other embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface.

The present disclosure may be useful for LED chips with current spreading structures that distribute current across active LED structure areas. Current spreading structures may include various electrically conductive layers, contacts, electrode extensions or fingers, and/or vias that effectively route current across an LED chip for reduced current crowding. In vertical LED chip structures, n-type and p-type contacts are typically made from opposing sides of the active LED structure. For larger area LED chips, contacts and corresponding electrode extensions may be arranged along a top of the active LED structure to contact one side of the active LED structure while bottom contacts and corresponding vias may be arranged to contact the opposing side of the active LED structure. As used herein, an electrode extension may refer to an elongated electrically conductive material that is continuous with and extends from an electrode pad or contact pad of an LED chip. The electrode pad may receive an external electrical connection, such as a wire bond, and the electrode extension extends away from the electrode pad for current spreading. As used herein, the terms electrode extension, contact extension, electrode finger, and contact finger may be used interchangeably.

As indicated above, principles of the present disclosure are applicable to active LED structures that emit peak wavelengths across a variety of visible and nonvisible ranges. In certain embodiments, aspects of the present disclosure are particularly useful for active LED structures configured to emit generally red or yellow light with a peak wavelength range of 600 nm to 700 nm. Certain embodiments as disclosed herein may be well suited for various sub-ranges within 600 nm to 700 nm, such as a peak wavelength range from 650 nm to 670 nm and/or a peak wavelength range from 610 nm to 630 nm, depending on the application. Such active LED structures may comprise GaP and/or GaAs based materials, such as aluminum indium gallium phosphide (AlInGaP) materials for any of the n-type, p-type, and active layers.

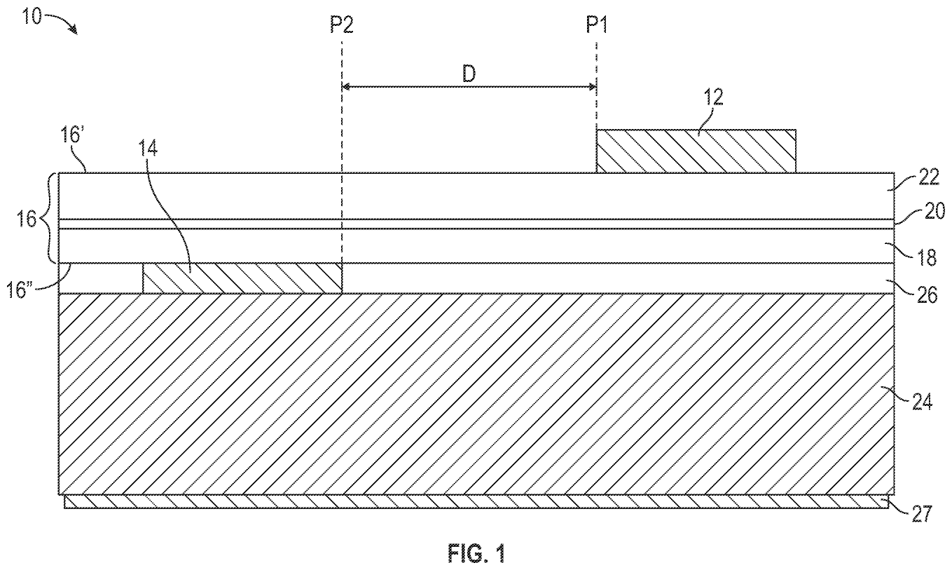

FIG. 1 is a cross-section of a portion of an LED chip 10 illustrating an electrode extension 12 and a via 14 arranged on opposing sides of an active LED structure 16 according to principles of the present disclosure. In FIG. 1, the active LED structure 16 is generally shown with a p-type layer 18, an n-type layer 22, and an active layer 20 therebetween. It is understood the active LED structure 16 may include additional layers and that each of the p-type layer 18, the n-type layer 22, and the active layer 20 may include multiple sublayers. The active LED structure 16 may be formed on a substrate 24. In certain embodiments, the substrate 24 embodies a carrier substrate on which the active LED structure 16 is supported. In such embodiments, the active LED structure 16 may first be grown on a growth substrate, followed by bonding the substrate 24 (e.g., carrier substrate) to a side of the active LED structure that is opposite the growth substrate, and then followed by removal of the growth substrate. In certain embodiments, the p-type layer 18 is between the active layer 20 and the carrier substrate 24 as illustrated in FIG. 1. In other embodiments, it is understood the doping or conductivity order may be reversed so that the n-type layer 22 is between the active layer 20 and the carrier substrate 24. The following discussion of FIG. 1 is in the context of the p-type layer 18 being closer to the carrier substrate 24 than the n-type layer 22. However, it is understood the principles are equally applicable to embodiments where the conductivity types are reversed. The substrate 24 may comprise many different materials, with silicon or other conductive materials being well suited for vertical chip structures.

In FIG. 1, the electrode extension 12 is on a first side 16′ (or top side) of the active LED structure 16 opposite the carrier substrate 24. As will be illustrated in later figures, the electrode extension 12 may extend from a top electrode pad that is also on the first side 16′. The electrode extension 12 provides a portion of an n-contact connection to the n-type layer 22. The LED chip 10 may include one or more electrically insulating layers 26 between the active LED structure 16 and the carrier substrate 24. In one example, the insulating layer 26 may form a portion of a mirror or reflective layer that is positioned to redirect downward propagating light back through the active LED structure 16 and out a top side of the LED chip 10. In this regard, the via 14 is arranged on a second side 16″ (or bottom side) of the active LED structure 16 that is opposite the first side 16′ to provide an electrically conductive path through the insulating layer 26 between the carrier substrate 24 and the active LED structure 16. A bottom electrode pad 27 may be formed on a bottom of the carrier substrate 24. By way of example, the via 14 provides a portion of a p-contact connection between the bottom electrode pad 27 and the p-type layer 18.

As illustrated in FIG. 1, a distance D may be defined as a lateral distance or spacing between the electrode extension 12 and the via 14, as measured in a horizontal plane between closest peripheral edges of the electrode extension 12 and the via 14. Since the electrode extension 12 and the via 14 are on opposing sides of the active LED structure 16, the distance D is measured between a first plane P1 vertically aligned with an edge of the electrode extension 12 and a second plane P2 vertically aligned with an edge of the via 14 that is closest to the electrode extension 12. When electrically activated, the active LED structure 16 generates light by the recombination of electrons and holes proximate the active layer 20. Increased recombination efficiency is realized in portions of the active LED structure 16 that are between the electrode extension 12 and the via 14. As illustrated, the via 14 may be laterally spaced from the electrode extension 12 by the distance D in order to reduce amounts of light lost to absorption by the electrode extension 12. For example, the electrode extension 12 may comprise conductive metals, such as gold (Au) or alloys thereof, that may reflect and/or absorb light generated in the active LED structure 16. By positioning the via 14 with a lateral spacing that is offset by the distance D from a position directly beneath the electrode extension 12, increased amounts of light may escape without interacting with the electrode extension 12. However, the electric potential of electrostatic fields decreases with increased distance D, so if the distance D is too great, the spacing between the via 14 and the electrode extension may include areas with significantly reduced field strength, thereby reducing recombination efficiency.

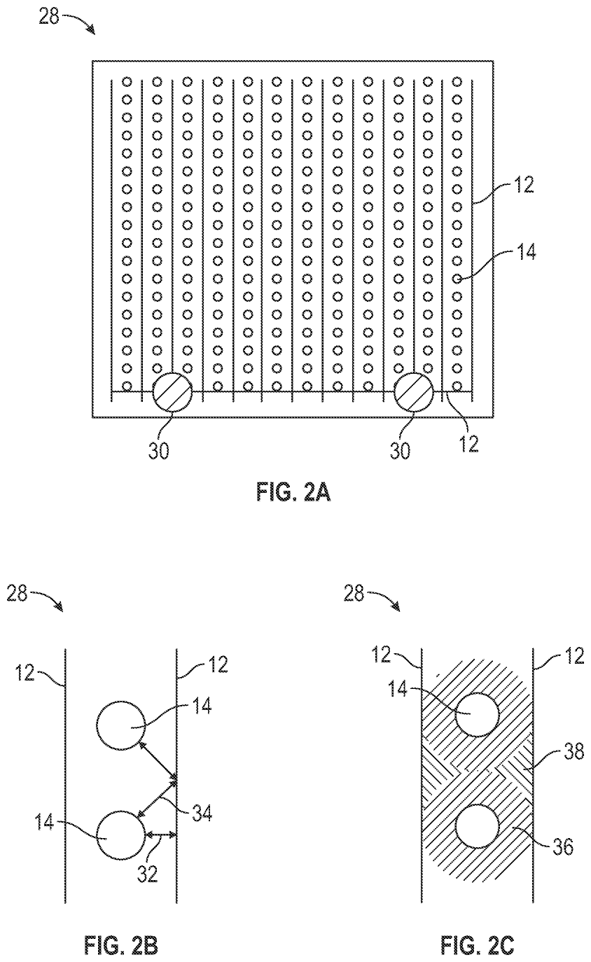

FIG. 2A is a top view of an LED chip 28 with an exemplary layout of electrode extensions 12 and vias 14 of FIG. 1. Since the view is from a top of the LED chip 28, the electrode extensions 12 are visible at the top surface of the LED chip 28. The vias 14, while being below the top surface of the LED chip 28, may still be visible therethrough as illustrated in FIG. 2A. The electrode extensions 12 are interconnected with one or more top electrode pads 30 on the top surface. In this manner, the electrode pads 30 may receive external electrical connections, such as wire bonds, and the electrode extensions 12 spread current along the area of the LED chip 28. In FIG. 2A, the electrode extensions 12 and the vias 14 are aligned in alternating linear columns from the top perspective. Such an arrangement provides variable distances between each electrode extension 12 and the closest via or vias 14. Accordingly, certain areas between electrode extensions 12 and closest vias 14 may be positioned in areas of reduced field strength that exhibit reduced recombination efficiency as illustrated and described for FIGS. 2B and 2C.

FIG. 2B is a top view of a portion of the LED chip 28 of FIG. 2A illustrating the variable distance between electrode extensions 14 and the closest vias 14. As illustrated, a first line 32 from the via 14 is perpendicular to the electrode extension 12 and defines shortest distance between the electrode extension 12 and the closest via 14. As the electrode extension 12 extends away from the via 14, a second line 34 defines a longer distance between the electrode extension 12 and the via 14. In FIG. 2B, the second line 34 extends from an edge of the via 14 to an edge of the electrode extension 12 that is positioned at a midpoint of the electrode extension 12 relative to the next via 14, thereby defining a longest distance from the electrode extension 12 to each closest via 14. Depending on the spacing between vias 14, the difference in distance (i.e., distance D of FIG. 1), the second line 34 may have a distance as much as 60% or 70% greater than the first line 32.

FIG. 2C is a top view of the portion of the LED chip 28 of FIG. 2B illustrating variations in electrostatic field strength with distance between electrode extensions 12 and vias 14. In FIG. 2C, first regions 36 are drawn in a circular manner around each via 14 to define areas with suitably high electrostatic field strength for improved recombination efficiency. Second regions 38 that correspond to longer distances between the electrode extensions 12 and vias 14, such as the second line 34 of FIG. 2B, correspond to areas with reduced electrostatic field strength and reduced recombination efficiency. In the context of FIG. 2A, the second regions 38 may be formed across the entire LED chip 28 with a cumulative effect on reduced efficiency.

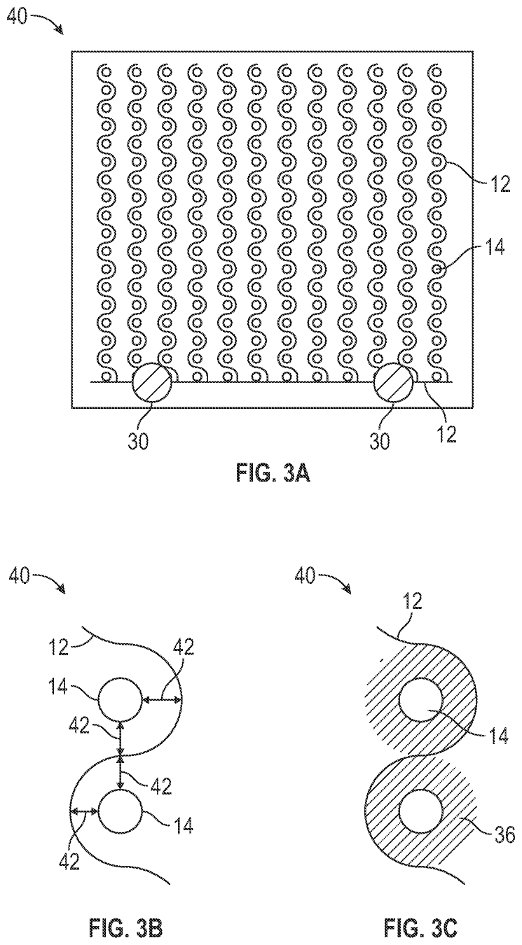

FIG. 3A is a top view of an LED chip 40 with an improved layout of electrode extensions 12 and vias 14 for enhanced emission efficiency. As illustrated, the electrode extensions 12 form a curved pattern across the LED chip 40. The curved pattern is positioned to curve while being laterally spaced from areas of the LED chip 40 (e.g., the active LED structure 16 of FIG. 1) that are vertically aligned with the underlying vias 14. The shape of the curved pattern of each electrode extension 12 is provided so that the spacing or distance D as illustrated in FIG. 1 is more uniform. In certain embodiments, the vias 14 are aligned in linear columns in a similar manner as FIG. 2A. However, the curved pattern of each electrode extension 12 is positioned to curve to the left and right of vertical positions of a corresponding column of vias 14 to maintain a more uniform spacing. In this regard, a single electrode extension 12 may extend between areas of the LED chip 40 (e.g., the active LED structure 16 of FIG. 1) that are vertically aligned with each pair of next adjacent vias 14 of a particular column. In certain embodiments, each electrode extension 12, except for the one connecting the two electrode pads 30, may form a serpentine shape relative to a corresponding column of vias 14.

FIG. 3B is a top view of a portion of the LED chip 40 of FIG. 3A illustrating the more uniform distance between the electrode extensions 12 and the closest vias 14. As illustrated, the curved and/or serpentine shape of the electrode extension 12 extends around and between the adjacent pair of vias 14. In this manner, a first line 42 defines a distance between any point on an edge of the electrode extension 12 to an edge of the closest via 14. As illustrated, the first line 42 in FIG. 3B corresponds to the distance D as illustrated in FIG. 1. The distance or spacing defined by the first line 42 may vary by no more than 25% or no more than 15% for any point along an edge of the electrode extension 12. In still further embodiments, the distance defined by the first line 42 may vary by no more than 10% or by no more than 5% for any point along an edge of the electrode extension 12. In practice, a majority of the spacings may be the same or within 1% of each other and the above percentages allow for some manufacturing tolerances and/or different distances near perimeter edges of the LED chip 40 and/or ends of the electrode extensions 12.

FIG. 3C is a top view of the portion of the LED chip 40 of FIG. 3B illustrating a more uniform electrostatic field strength between electrode extensions 12 and vias 14. In FIG. 3C, the first regions 36 are drawn in a circular manner around each via 14 to define areas with suitably high electrostatic field strength in a manner similar to FIG. 2C. As illustrated, the curved shape of the electrode extension 12 conforms to first regions 36 to avoid regions with reduced electrostatic field strength, such as the second regions 38 of FIG. 2C. Accordingly, the cumulative effect of reducing lower efficiency regions is multiplied across the LED chip 40 to provide increased emission efficiency.

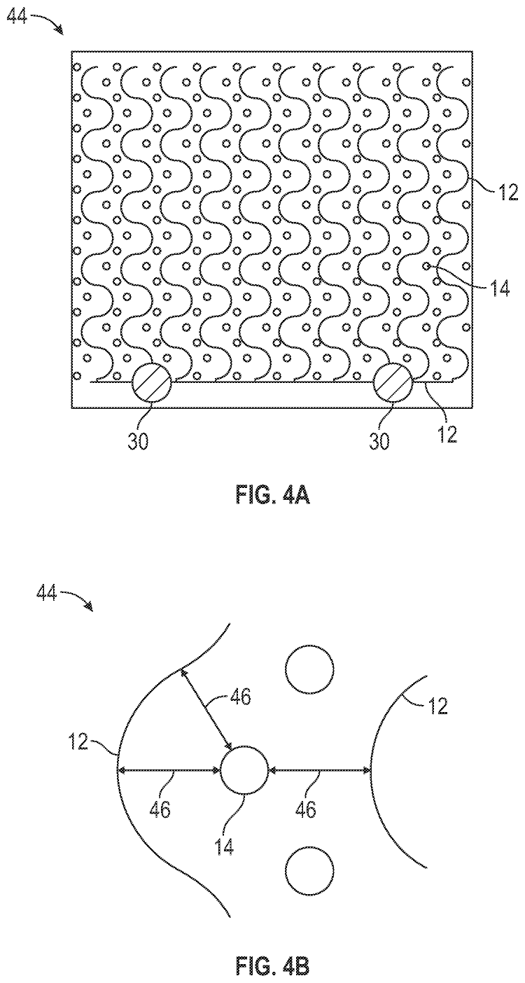

FIG. 4A is a top view of an LED chip 44 with another improved layout of electrode extensions 12 and vias 14 for enhanced emission efficiency. As illustrated, the electrode extensions 12 form curved and/or serpentine patterns across the LED chip 44. Instead of columns like those of FIG. 3A, the vias 14 are arranged in non-linear patterns. In certain embodiments, the vias 14 may have staggered positions relative to one another that generally follow the curvature of the electrode extensions 12. For example, the vias 14 between adjacent pairs of electrode extensions 12 may also be arranged in at least one curved and/or serpentine pattern that is positioned on areas of the LED chip 44 (or active LED structure 16 of FIG. 1) laterally spaced from areas vertically aligned with each electrode extension 12. In other embodiments, the vias 14 may form a hexagonal grid of vias 14.

FIG. 4B is a top view of a portion of the LED chip 44 of FIG. 4A illustrating the more uniform distance between the electrode extensions 12 and the closest vias 14. As illustrated, the layout of the vias 14 between the electrode extensions 12 generally follows the curved and/or serpentine shape of the electrode extensions 12. In this manner, a first line 46 defines a distance between any point on an edge of the electrode extension 12 to an edge of the closest via 14. As illustrated, the first line 46 in FIG. 4B corresponds to the distance D as illustrated in FIG. 1. The distance or spacing defined by the first line 46 may vary by no more than 25% or no more than 15% for any point along an edge of the electrode extension 12. In still further embodiments, the distance defined by the first line 46 may vary by no more than 10% or by no more than 5% for any point along an edge of the electrode extension 12. As described for FIG. 3B, a majority of the spacings for FIGS. 4A and 4B may be the same or within 1% of each other and the above percentages allow for some manufacturing tolerances and/or different distances near perimeter edges of the LED chip 40 and/or ends of the electrode extensions 12.

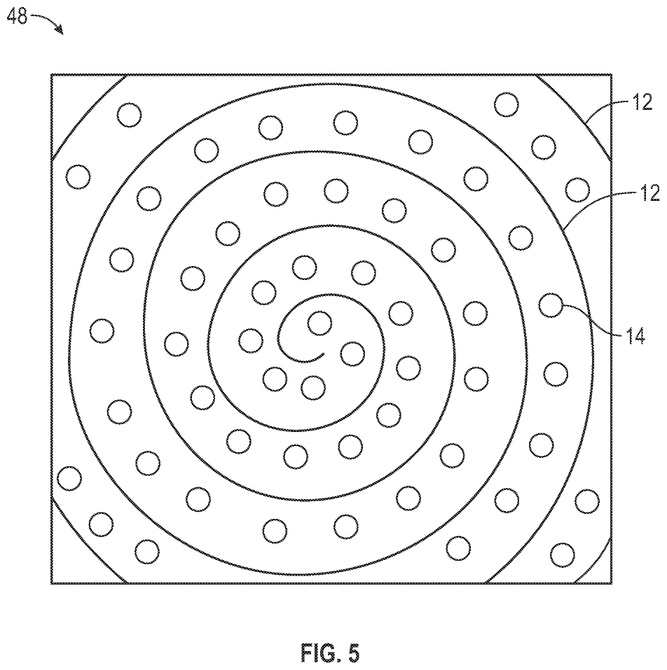

FIG. 5 is a top view of an LED chip 48 with another improved layout where the electrode extension 12 has a spiral shape relative to the vias 14 for enhanced emission efficiency. In FIG. 5, at least one electrode extension 12 forms the shape of a spiral along the LED chip 44, and vias 14 may be positioned between portions of the electrode extension 12 along the spiral. Depending on the layout, certain embodiments of the spiral shape for the electrode extension 12 may still maintain the distance or spacing percentages relative to vias as described above for FIG. 3A to 3C.

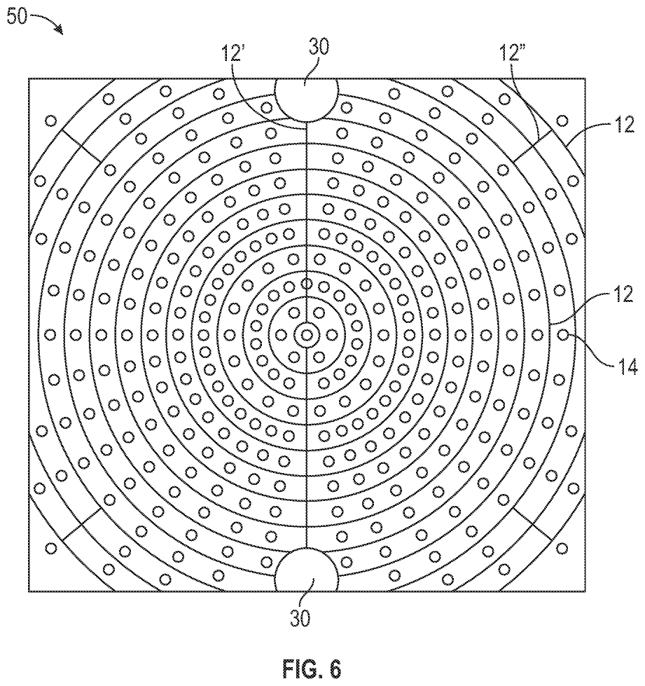

FIG. 6 is a top view of an LED chip 50 with another improved layout where the electrode extensions 12 form concentric rings relative to the vias 14 for enhanced emission efficiency. In FIG. 6, multiple electrode extensions 12 form concentric rings that are electrically coupled with one or more of the electrode pads 30. In certain embodiments, one or more additional electrode extensions 12′, 12″ may be positioned to electrically couple inner and/or outer rings together to ensure all electrode extensions 12 are connected to one or more of the electrode pads 30. For example, certain ones of the additional electrode extensions 12′ may be formed in a linear manner toward a center of the LED chip 50 for electrically coupling two or more electrode extensions 12 forming smaller diameter rings. Other ones of the additional electrode extensions 12″ may connect together radial electrode extensions 12 proximate corners of the LED chip 50. As illustrated, the vias 14 may be positioned between portions of the concentric rings of electrode extensions 12. Depending on the layout, certain embodiments of the electrode extensions 12 may still maintain the distance or spacing percentages relative to vias as described above for FIG. 3A to 3C.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
an active LED structure comprising a first layer of a first conductivity type, a second layer of a second conductivity type that is opposite the first conductivity type, and an active layer between the first layer and the second layer;
an electrode extension on a first side of the active LED structure; and
a plurality of vias on a second side of the active LED structure opposite the first side, the electrode extension curving on the first side of the active LED structure in positions that are laterally spaced from areas of the active LED structure that are vertically aligned with each via of the plurality of vias.

2. The LED chip of claim 1, wherein the plurality of vias are arranged in a linear column along the second side of the active LED structure.

3. The LED chip of claim 2, wherein the electrode extension forms a serpentine shape relative to the linear column.

4. The LED chip of claim 2, wherein the electrode extension extends on portions of the active LED structure that are between areas of the active LED structure vertically aligned with adjacent pairs of vias of the linear column.

5. The LED chip of claim 1, wherein the active LED structure comprises a group Ill-V material.

6. The LED chip of claim 1, wherein the active LED structure comprises aluminum indium gallium phosphide (AlInGaP).

7. The LED chip of claim 1, wherein the active LED structure is configured to provide a peak wavelength in a range from 600 nanometers (nm) to 700 nm.

8. The LED chip of claim 7, wherein the active LED structure is configured to provide a peak wavelength in a range from 650 nm to 670 nm.

9. The LED chip of claim 7, wherein the active LED structure is configured to provide a peak wavelength in a range from 610 nm to 630 nm.

10. The LED chip of claim 1, wherein the electrode extension forms a spiral shape on the first side of the active LED structure.

11. The LED chip of claim 1, wherein:
the electrode extension is one of a plurality of electrode extensions on the first side of the active LED structure; and
each electrode extension of the plurality electrode extensions forms a concentric ring on the first side of the active LED structure.

12. The LED chip of claim 11, further comprising an additional electrode extension that electrically couples at least two concentric rings together.

13. A light-emitting diode (LED) chip comprising:
an active LED structure comprising a first layer of a first conductivity type, a second layer of a second conductivity type that is opposite the first conductivity type, and an active layer between the first layer and the second layer;
a plurality of electrode extensions on a first side of the active LED structure, each electrode extension of the plurality of electrode extensions forming a serpentine shape along the first side of the active LED structure; and
a plurality of vias arranged on a second side of the active LED structure opposite the first side.

14. The LED chip of claim 13, wherein:
the plurality of vias is arranged in a plurality of linear columns along the second side of the active LED structure; and
the serpentine shape of at least one electrode extension of the plurality of electrode extensions extends along portions of the active LED structure that are between areas of the active LED structure vertically aligned with adjacent pairs of vias of a linear column of the plurality of linear columns.

15. The LED chip of claim 13, wherein the plurality of vias form at least one serpentine pattern on the second side of the active LED structure in a position that is laterally spaced from areas of the active LED structure vertically aligned with each electrode extension of the plurality of electrode extensions.

16. The LED chip of claim 13, wherein the plurality of vias are positioned such that a distance between any point on an edge of at least one electrode extension of the plurality of electrode extensions to a closest via of the plurality of vias varies by no more than twenty five percent along the at least one electrode extension, the distance being measured from a first plane aligned with the edge of the at least one electrode extension to a second plane aligned with a closest edge of the closest via of the plurality of vias.

17. The LED chip of claim 13, wherein the active LED structure is configured to provide a peak wavelength in a range from 600 nanometers (nm) to 700 nm.

18. A light-emitting diode (LED) chip comprising:
an active LED structure comprising a first layer of a first conductivity type, a second layer of a second conductivity type that is opposite the first conductivity type, and an active layer between the first layer and the second layer;
an electrode extension on a first side of the active LED structure; and
a plurality of vias on a second side of the active LED structure opposite the first side of the active LED structure, the plurality of vias positioned such that a distance between any point on an edge of the electrode extension to a closest via of the plurality of vias varies by no more than twenty five percent along the electrode extension, the distance being measured from a first plane aligned with the edge of the electrode extension to a second plane aligned with a closest edge of the closest via of the plurality of vias.

19. The LED chip of claim 18, wherein the distance varies by no more than ten percent along the electrode extension.

20. The LED chip of claim 18, wherein the distance varies by no more than five percent along the electrode extension.

21. The LED chip of claim 18, wherein the active LED structure is configured to provide a peak wavelength in a range from 600 nanometers (nm) to 700 nm.
